(19) United States
(12) Patent Application Publication
(10) Pub. No.: US 2025/0176197 A1
(43) Pub. Date: May 29, 2025

(54) METAL-OXIDE-SEMICONDUCTOR CAPACITOR

(71) Applicant: UNITED MICROELECTRONICS CORP., Hsin-Chu City (TW)

(72) Inventors: Hsin-Hsien Chen, New Taipei City (TW); Kuo-Hsing Lee, Hsinchu County (TW); Chih-Kai Kang, Tainan City (TW); Sheng-Yuan Hsueh, Tainan City (TW)

(73) Assignee: UNITED MICROELECTRONICS CORP., Hsin-Chu City (TW)

(21) Appl. No.: 18/957,888

(22) Filed: Nov. 25, 2024

(30) Foreign Application Priority Data
Nov. 28, 2023 (TW) 112146083

(51) Int. Cl. H01L 29/94

(52) U.S. Cl. CPC H10D 1/66

(57) ABSTRACT

A MOS capacitor includes a substrate of a first conductivity type including a fin surrounded by an isolation region. The fin protrudes from a top surface of the isolation region. A counter-doping region of a second conductivity type is disposed in the fin and serves as a first electrode plate of the MOS capacitor. A capacitor dielectric layer covers a sidewall and a top surface of the fin. A metal gate covers the capacitor dielectric layer and serves as a second electrode plate of the MOS capacitor.

### BACKGROUND OF THE INVENTION

### 1. Field of the Invention

The present invention relates to the field of semiconductor technology, and in particular to a metal-oxide-semiconductor (MOS) capacitor structure.

### 2. Description of the Prior Art

To be able to manufacture integrated circuits such as memories, logic devices and other components with higher integration densities, an improved method for further reductions in the size of capacitors (e.g. metal-oxide-semiconductor capacitors) and field effect transistors (e.g. metal-oxide-semiconductor field effect transistor) is needed. By reducing the overall size and operating voltage of the device while maintaining the electrical characteristics of the device, scaling can increase device density and improve device operation performance.

### SUMMARY OF THE INVENTION

It is one object of the present invention to provide an improved metal-oxide-semiconductor (MOS) capacitor structure in order to solve the deficiencies or shortcomings of the existing technology.

One aspect of the invention provides a metal-oxide-semiconductor (MOS) capacitor including a substrate of a first conductivity type comprising a fin surrounded by an isolation region, wherein the fin protrudes from a top surface of the isolation region; a counter-doping region of a second conductivity type in the fin serving as a first electrode plate of the MOS capacitor; a capacitor dielectric layer covering a sidewall and a top surface of the fin; and a metal gate covering the capacitor dielectric layer and serving as a second electrode plate of the MOS capacitor.

According to some embodiments, the metal gate covers the sidewall and the top surface of the fin.

According to some embodiments, the MOS capacitor further includes an interlayer dielectric layer on the metal gate; and a contact structure embedded in the interlayer dielectric layer, wherein the contact structure is electrically connected to the metal gate.

According to some embodiments, the contact structure is disposed directly above the isolation region.

According to some embodiments, the counter-doping region is an N⁺ doped region.

According to some embodiments, the first conductivity type is P type and the second conductivity type is N type.

According to some embodiments, the fin extends along a first direction and the metal gate extends along a second direction that is orthogonal to the first direction.

According to some embodiments, the fin further includes a first source/drain region and a second source/drain region on opposing sides of the metal gate.

According to some embodiments, the fin further includes a first epitaxial layer on the first source/drain region and a second epitaxial layer on the second source/drain region, wherein the first epitaxial layer and the second epitaxial layer are electrically connected to the counter-doping region.

According to some embodiments, the first epitaxial layer and the second epitaxial layer comprise SiP.

Another aspect of the invention provides a metal-oxide-semiconductor (MOS) capacitor including a substrate of a first conductivity type comprising a fin surrounded by an isolation region, wherein the fin protrudes from a top surface of the isolation region; a counter-doping region of a second conductivity type in the fin serving as a first electrode plate of the MOS capacitor; a capacitor dielectric layer covering only a top surface of the fin; and a metal gate disposed on the capacitor dielectric layer and covering only a top surface of the fin, wherein the metal gate serves as a second electrode plate of the MOS capacitor.

According to some embodiments, the metal gate does not covers sidewall of the fin.

According to some embodiments, the MOS capacitor further includes an interlayer dielectric layer on the metal gate; and a contact structure embedded in the interlayer dielectric layer, wherein the contact structure is electrically connected to the metal gate.

According to some embodiments, the contact structure is disposed directly above the fin. According to some embodiments, the counter-doping region is an N⁺ doped region.

According to some embodiments, the first conductivity type is P type and the second conductivity type is N type.

According to some embodiments, the fin extends along a first direction and the metal gate extends along a second direction that is orthogonal to the first direction.

According to some embodiments, the fin further includes a first source/drain region and a second source/drain region on opposing sides of the metal gate.

According to some embodiments, the fin further includes a first epitaxial layer on the first source/drain region and a second epitaxial layer on the second source/drain region, wherein the first epitaxial layer and the second epitaxial layer are electrically connected to the counter-doping region.

According to some embodiments, the first epitaxial layer and the second epitaxial layer comprise SiP.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial top view of a semiconductor structure according to an embodiment of the present invention.

FIG. 2 is a schematic cross-sectional view taken along line I-I′ in FIG. 1.

FIG. 3 is a schematic cross-sectional view taken along line II-II′ in FIG. 1.

FIG. 4 is a partial top view of a semiconductor structure according to another embodiment of the present invention.

FIG. 5 is a schematic cross-sectional view taken along line I-I′ in FIG. 4.

FIG. 6 is a schematic cross-sectional view taken along line II-II′ in FIG. 4.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

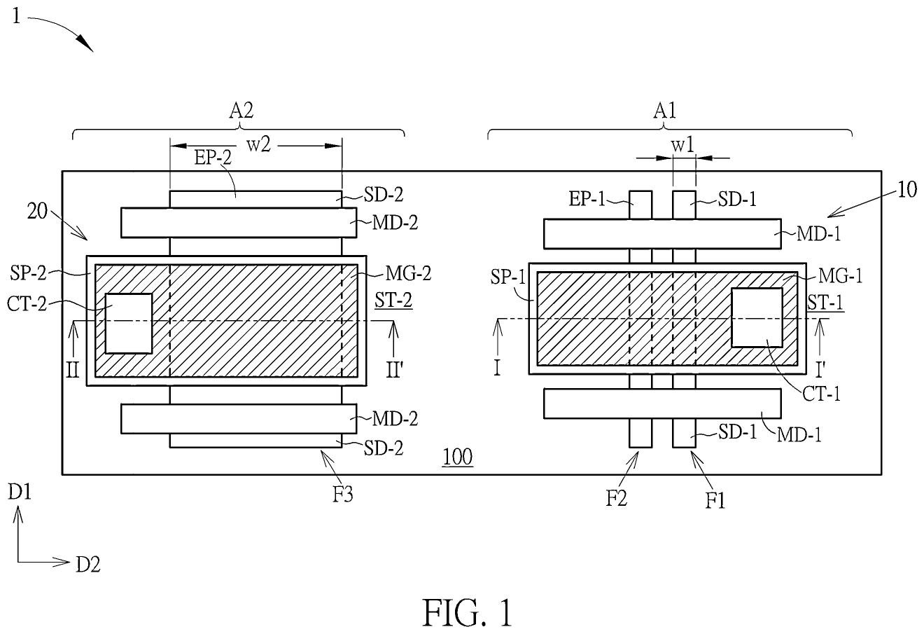

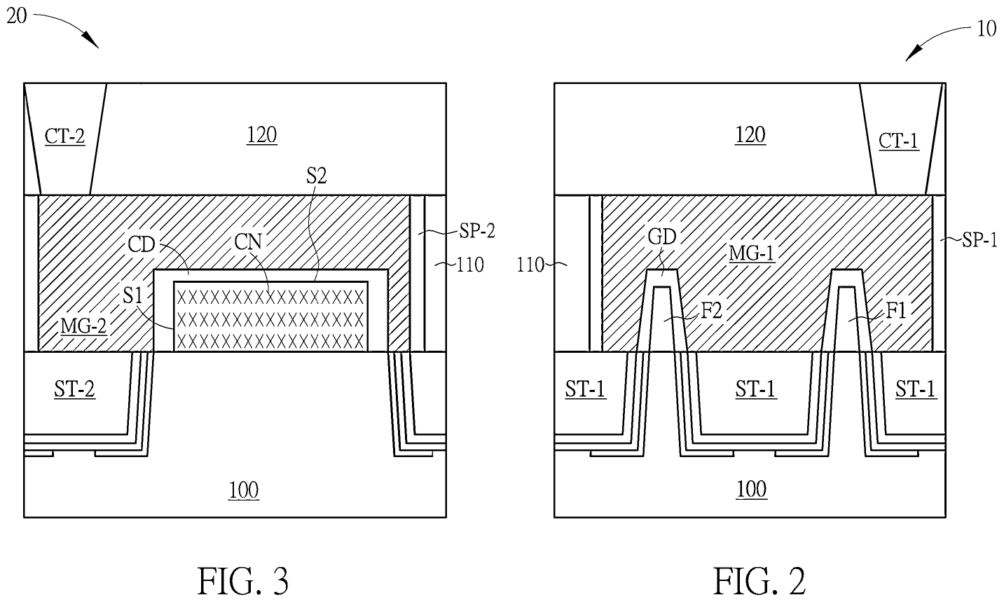

Please refer to FIG. 1 to FIG. 3, wherein FIG. 1 is a partial top view of a semiconductor structure according to an embodiment of the present invention, FIG. 2 is a schematic cross-sectional view taken along line I-I′ in FIG. 1, and FIG. 3 is a schematic cross-sectional view taken along line II-II′ in FIG. 1. As shown in FIG. 1 to FIG. 3, the semiconductor structure 1comprises a substrate 100 with a first conductivity type. According to an embodiment of the present invention, the substrate 100 may be, for example, a silicon substrate, but is not limited thereto. According to an embodiment of the present invention, the first conductivity type may be, for example, P type. In the first area A1 of the an embodiment of the present invention, for example, the first area A1 may be a logic circuit area or a peripheral circuit area, but is not limited thereto.

According to an embodiment of the present invention, the circuit element 10 includes a plurality of fins, such as fins F1 and fins F2, extending along a first direction D1. According to an embodiment of the present invention, the fins F1 and F2 protrude from the top surface of the isolation region ST-1, and the fins F1 and the fins F2 have a width w1. According to an embodiment of the present invention, the isolation region ST-1 is a shallow trench isolation (STI) structure.

According to an embodiment of the present invention, the circuit element 10 further includes a metal gate MG-1 located on the fin F1 and the fin F2 and extending along a second direction D2, and a gate dielectric layer GD. The gate dielectric layer GD is located between the metal gate MG-1 and the fins F1 and F2. According to an embodiment of the present invention, the first direction D1 is orthogonal to the second direction D2.

According to an embodiment of the present invention, the circuit element 10 further includes a spacer SP-1, such as a silicon nitride layer, located on the sidewall of the metal gate MG-1. According to an embodiment of the present invention, the metal gate MG-1 and the spacer SP-1 are formed in the interlayer dielectric layer 110. According to an embodiment of the present invention, an interlayer dielectric layer 120 is formed on the metal gate MG-1 and the interlayer dielectric layer 110.

According to an embodiment of the present invention, the metal gate MG-1 can be formed using a replacement metal gate (RMG) process, where the metal gate MG-1 can include a high dielectric constant material layer, a barrier layer, a work function layer and low-resistance metal layer. Since the gate metal structures are well-known, they will not be described in detail here for the sake of simplicity.

According to an embodiment of the present invention, as shown in FIG. 1, the fin F1 and the fin F2 further include source/drain regions SD-1 located on opposite sides of the metal gate MG-1. The source/drain regions SD-1 on adjacent fins F1 and fins F2 may be interconnected through conductive strips MD-1 extending along the second direction D2. An epitaxial layer EP-1, such as SiP or SiGe, may be formed on the source/drain region SD-1.

According to an embodiment of the present invention, a contact structure CT-1 is formed in the interlayer dielectric layer 120 and is electrically connected to the underlying metal gate MG-1. According to an embodiment of the present invention, for example, the contact structure CT-1 may include metal. According to an embodiment of the present invention, the contact structure CT-1 does not overlap the fins F1 and F2. As shown in FIG. 1, the contact structure CT-1 is located directly above the isolation region ST-1.

As shown in FIG. 1 and FIG. 3, a metal oxide semiconductor (MOS) capacitor 20 is formed in the second area A2 of the substrate 100. According to an embodiment of the present invention, the MOS capacitor 20 includes the substrate 100 of the first conductive type that includes a fin F3 surrounded by an isolation region ST-2. The fin F3 protrudes from the top surface of the isolation area ST-2 and extends along the first direction D1. According to an embodiment of the present invention, the fin F3 has a width w2, wherein the width w2 of the fin F3 is greater than the width w1 of the fin F1 and the fin F2.

According to an embodiment of the present invention, the MOS capacitor 20 further includes counter-doping region CN of the second conductivity type, which is located in the fin F3 and serves as the first electrode plate of the MOS capacitor 20. According to an embodiment of the present invention, the counter-doping region CN may be an N⁺ doped region. According to an embodiment of the present invention, the counter-doping region CN occupies the entire portion of the fin F3 above the isolation region ST-2. According to an embodiment of the present invention, for example, the first conductivity type is P type, and the second conductivity type is N type.

According to an embodiment of the present invention, the MOS capacitor 20 further includes a capacitor dielectric layer CD, covering the sidewalls S1 and the top surface S2 of the fin F3, and a metal gate MG-2, covering the capacitor dielectric layer CD. The metal gate MG-2 functions as the second electrode plate of the MOS capacitor 20. According to an embodiment of the present invention, the metal gate MG-2 also covers the side walls S1 and the top surface S2 of the fin F3. According to an embodiment of the present invention, the metal gate MG-2 extends along the second direction D2 that is orthogonal to the first direction D1.

The metal gate MG-2 of the MOS capacitor 20 covers a monolithic and large-area fin F3. The width w2 of the fin F3 is larger than the width w1 of the fin F1 and the fin F2. For example, w2=5w1 or w2=6w1. The advantage is that the impact of the ion implantation process used to form the counter-doping region CN on the subsequent fin profile can be reduced.

According to an embodiment of the present invention, the MOS capacitor 20 further includes an interlayer dielectric layer 120 located on the metal gate MG-2, and a contact structure CT-2 embedded in the interlayer dielectric layer 120. The contact structure CT-2 is electrically connected to the metal gate MG-2. According to an embodiment of the present invention, the contact structure CT-2 is disposed directly above the isolation region ST-2. According to an embodiment of the present invention, the contact structure CT-2 does not overlap the underlying fin F3.

According to an embodiment of the present invention, the fin F3 further includes source/drain regions SD-2, which are respectively located on opposing sides of the metal gate MG-2. The source/drain regions SD-2 on the fin F3 may be interconnected through the conductive strip MD-2 extending along the second direction D2. According to an embodiment of the present invention, the fin F3 further includes an epitaxial layer EP-2 located on the source/drain region SD-2. The epitaxial layer EP-2 is electrically connected to the counter-doping region CN. According to an embodiment of the present invention, for example, the epitaxial layer EP-2 may include SiP.

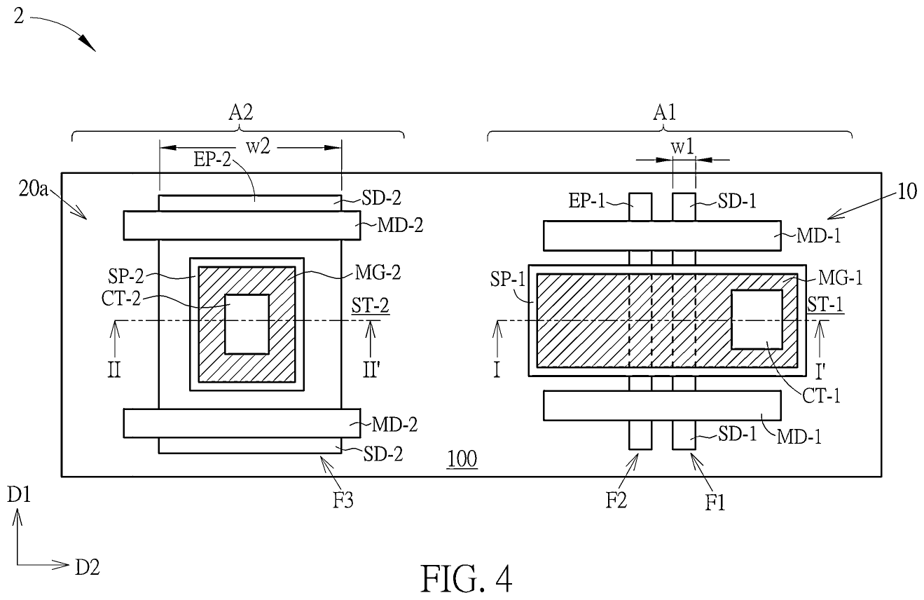

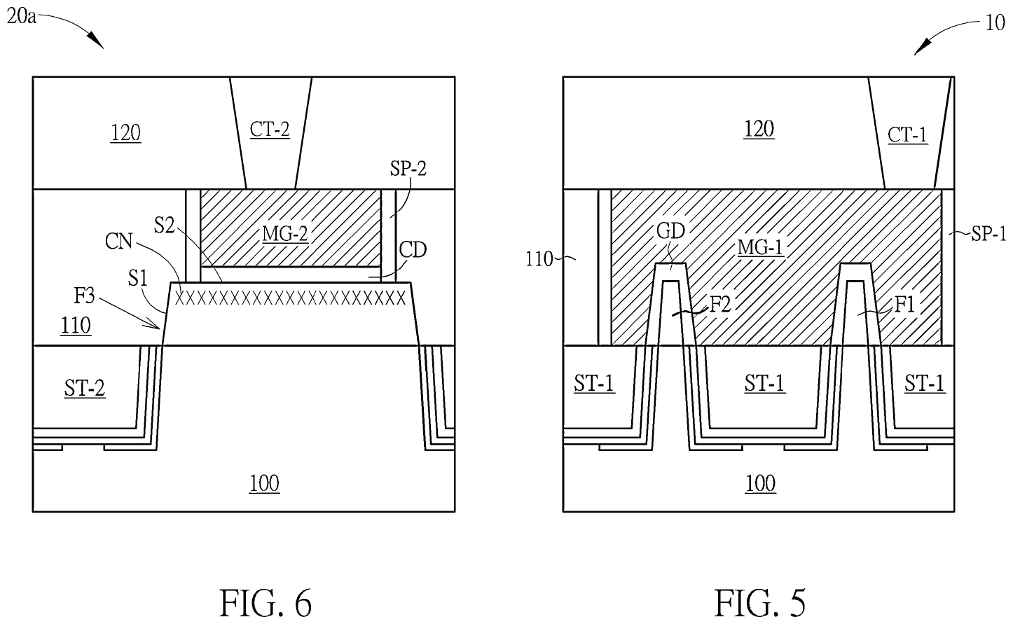

Please refer to FIG. 4 to FIG. 6, wherein FIG. 4 is a partial top view of a semiconductor structure according to another embodiment of the present invention, FIG. 5 is a schematic cross-sectional view taken along line I-I′ in FIG. 4, and FIG. 6 is a schematic cross-sectional view taken along line II-II′ in FIG. 4. As shown in FIG. 4 and FIG. 5, likewise, the semiconductor structure 2 includes a substrate 100 of a first conductivity type. For example, the substrate 100 may be a silicon substrate, but is not limited thereto. The first conductivity type may be P type. In the first area A1 of the substrate 100, a circuit element 10, such as a fin field effect transistor, is formed. According to an embodiment of the present invention, for example, the first area A1 may be a logic circuit area or a peripheral circuit area, but is not limited thereto.

According to an embodiment of the present invention, the circuit element 10 includes a plurality of fins, such as fins F1 and fins F2, extending along the first direction D1. According to an embodiment of the present invention, the fins F1 and F2 protrude from the top surface of the isolation region ST-1, and the fins F1 and the fins F2 have a width w1. According to an embodiment of the present invention, the isolation region ST-1 is a shallow trench insulation (STI) structure.

According to an embodiment of the present invention, the circuit element 10 further includes a metal gate MG-1 located on the fin F1 and the fin F2 and extending along the second direction D2, and a gate dielectric layer GD. The gate dielectric layer GD is located between the metal gate MG-1 and the fins F1 and F2. According to an embodiment of the present invention, the first direction D1 is orthogonal to the second direction D2.

According to an embodiment of the present invention, the circuit element 10 further includes a spacer SP-1, such as a silicon nitride layer, located on the sidewall of the metal gate MG-1. According to an embodiment of the present invention, the metal gate MG-1 and the spacer SP-1 are formed in the interlayer dielectric layer 110. According to an embodiment of the present invention, an interlayer dielectric layer 120 is formed on the metal gate MG-1 and the interlayer dielectric layer 110.

According to an embodiment of the present invention, metal gate MG-1 may be formed using a replacement metal gate (RMG) process. The metal gate MG-1 may include a high dielectric constant material layer, a barrier layer, a work function layer and a low-resistance metal layer, etc., which is a well-known technology and will not be described in detail here for the sake of simplicity.

According to an embodiment of the present invention, as shown in FIG. 4, the fin F1 and the fin F2 further include source/drain regions SD-1 located on opposing sides of the metal gate MG-1. The source/drain regions SD-1 on adjacent fins F1 and fins F2 may be interconnected through conductive strips MD-1 extending along the second direction D2. An epitaxial layer EP-1, such as SiP or SiGe, may be formed on the source/drain region SD-1.

According to an embodiment of the present invention, a contact structure CT-1 is formed in the interlayer dielectric layer 120 and is electrically connected to the underlying metal gate MG-1. According to an embodiment of the present invention, the contact structure CT-1 does not overlap the fins F1 and F2. As shown in FIG. 4, the contact structure CT-1 is located directly above the isolation region ST-1.

As shown in FIG. 4 and FIG. 6, a metal oxide semiconductor (MOS) capacitor 20a is formed in the second area A2 of the substrate 100. According to an embodiment of the present invention, the MOS capacitor 20a includes the substrate 100 of the first conductive type, and includes fin F3 surrounded by the isolation region ST-2. The fin F3 protrudes from the top surface of the isolation region ST-2 and extends along the first in direction D1. According to an embodiment of the present invention, the fin F3 has a width w2, wherein the width w2 of the fin F3 is greater than the width w1 of the fin F1 and the fin F2.

According to an embodiment of the present invention, the MOS capacitor 20a further includes a counter-doping region CN of the second conductivity type, which is located in the fin F3 and serves as the first electrode plate of the MOS capacitor 20a. According to an embodiment of the present invention, the counter-doping region CN may be an N⁺ doped region. Compared with FIG. 3, the depth of the counter-doping region CN in FIG. 6 is shallower. According to an embodiment of the present invention, for example, the first conductivity type is P type, and the second conductivity type is N type.

According to an embodiment of the present invention, the MOS capacitor 20a further includes a capacitor dielectric layer CD, which only covers the top surface S2 of the fin F3, and a metal gate MG-2, which covers the capacitor dielectric layer CD and serves as the second electrode plate of the MOS capacitor 20a. According to an embodiment of the present invention, the metal gate MG-2 also only covers the top surface S2 of the fin F3. According to an embodiment of the present invention, the metal gate MG-2 does not cover the sidewall S1 of the fin F3. According to an embodiment of the present invention, the metal gate MG-2 extends along the second direction D2 that is orthogonal to the first direction D1.

The metal gate MG-2 of the MOS capacitor 20a covers a monolithic and large-area fin F3. The width w2 of the fin F3 is larger than the width w1 of the fin F1 and the fin F2. For example, w2=5w1 or w2=6w1. The advantage is that the impact of the ion implantation process used to form the counter-doping region CN on the subsequent fin profile can be reduced. In addition, the capacitor dielectric layer CD and the metal gate MG-2 do not cover the sidewall S1 of the fin F3, which can avoid the influence of the thickness variation of the capacitor dielectric layer.

According to an embodiment of the present invention, the MOS capacitor 20a further includes an interlayer dielectric layer 120 located on the metal gate MG-2, and a contact structure CT-2 embedded in the interlayer dielectric layer 120. The contact structure CT-2 is electrically connected to the metal gate MG-2. According to an embodiment of the present invention, the contact structure CT-2 is disposed directly above the fin F3. According to an embodiment of the present invention, as shown in FIG. 4, the contact structure CT-2 completely overlaps the fin F3.

According to an embodiment of the present invention, the fin F3 further includes source/drain regions SD-2, which are respectively located on opposing sides of the metal gate MG-2. According to an embodiment of the present invention, the fin F3 further includes an epitaxial layer EP-2 located on the source/drain region SD-2. The epitaxial layer EP-2 is electrically connected to the counter-doping region CN. The source/drain regions SD-2 on the fin F3 may be interconnected through the conductive strip MD-2 extending along the second direction D2. According to an embodiment of the present invention, for example, the epitaxial layer EP-2 may include SiP.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A metal-oxide-semiconductor (MOS) capacitor, comprising:
a substrate of a first conductivity type comprising a fin surrounded by an isolation region, wherein the fin protrudes from a top surface of the isolation region;
a counter-doping region of a second conductivity type in the fin serving as a first electrode plate of the MOS capacitor;
a capacitor dielectric layer covering a sidewall and a top surface of the fin; and
a metal gate covering the capacitor dielectric layer and serving as a second electrode plate of the MOS capacitor.

2. The MOS capacitor according to claim 1, wherein the metal gate covers the sidewall and the top surface of the fin.

3. The MOS capacitor according to claim 1 further comprising:
an interlayer dielectric layer on the metal gate; and
a contact structure embedded in the interlayer dielectric layer, wherein the contact structure is electrically connected to the metal gate.

4. The MOS capacitor according to claim 3, wherein the contact structure is disposed directly above the isolation region.

5. The MOS capacitor according to claim 1, wherein the counter-doping region is an N⁺ doped region.

6. The MOS capacitor according to claim 1, wherein the first conductivity type is P type and the second conductivity type is N type.

7. The MOS capacitor according to claim 1, wherein the fin extends along a first direction and the metal gate extends along a second direction that is orthogonal to the first direction.

8. The MOS capacitor according to claim 1, wherein the fin further comprises:
a first source/drain region and a second source/drain region on opposing sides of the metal gate.

9. The MOS capacitor according to claim 8, wherein the fin further comprises:
a first epitaxial layer on the first source/drain region and a second epitaxial layer on the second source/drain region, wherein the first epitaxial layer and the second epitaxial layer are electrically connected to the counter-doping region.

10. The MOS capacitor according to claim 9, wherein the first epitaxial layer and the second epitaxial layer comprise SiP.

11. A metal-oxide-semiconductor (MOS) capacitor, comprising:
a substrate of a first conductivity type comprising a fin surrounded by an isolation region, wherein the fin protrudes from a top surface of the isolation region;
a counter-doping region of a second conductivity type in the fin serving as a first electrode plate of the MOS capacitor;
a capacitor dielectric layer covering only a top surface of the fin; and
a metal gate disposed on the capacitor dielectric layer and covering only a top surface of the fin, wherein the metal gate serves as a second electrode plate of the MOS capacitor.

12. The MOS capacitor according to claim 11, wherein the metal gate does not covers sidewall of the fin.

13. The MOS capacitor according to claim 11 further comprising:
an interlayer dielectric layer on the metal gate; and
a contact structure embedded in the interlayer dielectric layer, wherein the contact structure is electrically connected to the metal gate.

14. The MOS capacitor according to claim 13, wherein the contact structure is disposed directly above the fin.

15. The MOS capacitor according to claim 11, wherein the counter-doping region is an N⁺ doped region.

16. The MOS capacitor according to claim 11, wherein the first conductivity type is P type and the second conductivity type is N type.

17. The MOS capacitor according to claim 11, wherein the fin extends along a first direction and the metal gate extends along a second direction that is orthogonal to the first direction.

18. The MOS capacitor according to claim 11, wherein the fin further comprises:
a first source/drain region and a second source/drain region on opposing sides of the metal gate.

19. The MOS capacitor according to claim 18, wherein the fin further comprises:
a first epitaxial layer on the first source/drain region and a second epitaxial layer on the second source/drain region, wherein the first epitaxial layer and the second epitaxial layer are electrically connected to the counter-doping region.

20. The MOS capacitor according to claim 19, wherein the first epitaxial layer and the second epitaxial layer comprise SiP.
